(19) United States
(12) Patent Application Publication
(10) Pub. No.: US 2020/0007098 A1
(43) Pub. Date: Jan. 2, 2020

(54) Dual-Mode Amplification by Varying a Load Impedance

(71) Applicant: Qualcomm Incorporated, San Diego, CA (US)

(72) Inventors: Hung-Min Cheng, Saratoga, CA (US); Ara Bicakci, Belmont, CA (US); Haitao Gan, Santa Clara, CA (US); Shen Wang, Palo Alto, CA (US); Mounir Bohsali, Danville, CA (US); Hedieh Elyasi, Santa Clara, CA (US); Beomsup Kim, Los Altos Hills, CA (US)

(21) Appl. No.: 16/115,448

(22) Filed: Aug. 28, 2018

Related U.S. Application Data
(60) Provisional application No. 62/692,397, filed on Jun. 29, 2018.

(51) Int. Cl. H03F 3/217; H03F 1/02; H03F 3/21; H03F 3/68

(52) U.S. Cl. CPC H03F 3/217; H03F 1/0277; H03F 2200/451; H03F 3/68; H03F 2200/111; H03F 3/211

(57) ABSTRACT

An apparatus is disclosed for dual-mode amplification by varying a load impedance. In an example aspect, the apparatus includes a low-noise amplifier, a first component, a second component, and a switch. The first component has a first input impedance. The second component is coupled between the low-noise amplifier and the first component. The second component has a second input impedance that is greater than the first input impedance. The switch is coupled in parallel with the second component between the low-noise amplifier and the first component. The switch is configured to selectively be in an open state to engage the second component or a closed state to bypass the second component.

### CROSS-REFERENCE TO RELATED APPLICATION(S)

This application claims the benefit of U.S. Provisional Application No. 62/692,397, filed 29 Jun. 2018, the disclosure of which is hereby incorporated by reference in its entirety herein.

### TECHNICAL FIELD

This disclosure relates generally to wireless transceivers and, more specifically, to selectively operating a low-noise amplifier in a current mode or a voltage mode by varying a load impedance of the low-noise amplifier.

### BACKGROUND

Electronic devices use radio-frequency (RF) signals to communicate information. These radio-frequency signals enable users to talk with friends, download information, share pictures, remotely control household devices, receive global positioning information, and so forth. Sometimes a variety of different types of wireless communication signals may be present at a given time and within a similar frequency band. The different types of signals may include, for example, Bluetooth™ signals, Wi-Fi™ signals, or cellular signals. These signals may be associated with a same electronic device, such as an electronic device that transmits a Wi-Fi™ signal while attempting to receive a Bluetooth™ signal.

In other cases, the signals may be associated with different electronic devices. For example, another electronic device may transmit a cellular signal while the electronic device attempts to receive the Bluetooth™ signal. Because these signals have similar frequencies, it may be challenging for the electronic device to separate the transmitted signals from a target receive signal. As such, the transmitted signals may interfere with reception of the target receive signal and cause a receiver of the electronic device to become saturated. Consequently, the receiver may experience a degraded dynamic range, which makes detecting a low-power signal challenging.

### SUMMARY

An apparatus is disclosed that implements dual-mode amplification by varying a load impedance. The described techniques vary a load impedance of a low-noise amplifier according to whether or not interference is present. Based on the load impedance, the low-noise amplifier operates in a current mode or a voltage mode. In the current mode, the low-noise amplifier experiences a relatively small load impedance that results in an amplified signal produced by the low-noise amplifier having a small voltage swing. In the voltage mode, the low-noise amplifier experiences a relatively large load impedance that results in the amplified signal having a large voltage swing. While the voltage mode enables a target sensitivity and reverse isolation to be realized to support far distance communications, the current mode reduces a likelihood that the receiver becomes saturated. Through the use of these two modes, a receiver can continue to operate and detect a received signal whether or not interference is present. In some implementations, an interference awareness module determines whether interference is present and causes the low-noise amplifier to dynamically switch between the different modes of operation based on this determination.

In an example aspect, an apparatus is disclosed. The apparatus includes a low-noise amplifier, a first component, a second component, and a switch. The first component has a first input impedance. The second component is coupled between the low-noise amplifier and the first component. The second component has a second input impedance that is greater than the first input impedance. The switch is coupled in parallel with the second component between the low-noise amplifier and the first component. The switch is configured to selectively be in an open state to engage the second component or a closed state to bypass the second component.

In an example aspect, an apparatus is disclosed. The apparatus includes a low-noise amplifier, a first component, and a second component. The first component has a first input impedance. The second component is coupled between the low-noise amplifier and the first component. The second component is configured to have a second input impedance that is greater than the first input impedance. The apparatus also includes switch means for selectively causing a load impedance of the low-noise amplifier to be based on the first input impedance or the second input impedance.

In an example aspect, a method for dual-mode amplification by varying a load impedance is disclosed. The method includes receiving a high-power signal at a first time and causing a load impedance of a low-noise amplifier to be at a first load impedance at the first time. The method also includes amplifying the high-power signal using the low-noise amplifier at the first time. The method additionally includes receiving a low-power signal at a second time and causing the load impedance of the low-noise amplifier to be at a second load impedance at the second time. The second load impedance is greater than the first load impedance. The method further includes amplifying the low-power signal using the low-noise amplifier at the second time.

In an example aspect, an apparatus is disclosed. The apparatus includes a receiver, which includes a low-noise amplifier, a mixer, a transconductance amplifier, and a switch. The transconductance amplifier is coupled between the low-noise amplifier and the mixer. The switch is coupled in parallel with the transconductance amplifier between the low-noise amplifier and the mixer.

### BRIEF DESCRIPTION OF DRAWINGS

FIG. 1 illustrates an example operating environment for dual-mode amplification by varying a load impedance.

FIG. 2 illustrates an example sequence flow diagram for dual-mode amplification by varying a load impedance.

FIG. 3 illustrates an example wireless transceiver including a low-noise amplifier for dual-mode amplification by varying a load impedance.

FIG. 4-1 illustrates an example voltage-mode operation of a low-noise amplifier within a receiver for dual-mode amplification by varying a load impedance.

FIG. 4-2 illustrates an example current-mode operation of a low-noise amplifier within a receiver for dual-mode amplification by varying a load impedance.

FIG. 5 is a flow diagram illustrating an example process for dual-mode amplification by varying a load impedance.

### DETAILED DESCRIPTION

Electronic devices use radio-frequency (RF) signals to communicate information. These radio-frequency signals enable users to talk with friends, download information, share pictures, remotely control household devices, receive global positioning information for navigational applications, and so forth. Sometimes a variety of different types of wireless communication signals may be present at a given time and within a given frequency band. These different types of signals may include, for example, Bluetooth™ signals, Wi-FI™ signals, or cellular signals. In some cases, these signals are associated with an electronic device. The electronic device can, for instance, transmit a Wi-Fi™ signal while attempting to receive a Bluetooth™ signal. In other cases, the signals may be associated with different electronic devices. For example, another electronic device may transmit a cellular signal while the electronic device attempts to receive the Bluetooth™ signal.

Because these signals have similar frequencies, it may be challenging for the electronic device to separate the transmitted signals from a target receive signal. As such, the transmitted signals may interfere with reception of the target receive signal and cause a receiver of the electronic device to become saturated. Consequently, the receiver may experience a degraded dynamic range, which makes detecting a low-power signal challenging. To avoid saturating the receiver, some techniques may bias the low-noise amplifier differently to decrease a gain of a low-noise amplifier if a high-power signal is received. However, this approach can decrease both a noise figure of the receiver and linearity performance, which reduces a sensitivity of the receiver.

In contrast, techniques for dual-mode amplification by varying a load impedance are described herein. The described techniques vary a load impedance of a low-noise amplifier according to whether or not interference is present. Based on the load impedance, the low-noise amplifier operates in a current mode or a voltage mode. In the current mode, the low-noise amplifier experiences a relatively small load impedance that results in an amplified signal produced by the low-noise amplifier having a small voltage swing. In the voltage mode, the low-noise amplifier experiences a relatively large load impedance that results in the amplified signal having a large voltage swing. While the voltage mode enables a target sensitivity and reverse isolation to be realized to support far distance communications, the current mode reduces a likelihood that the receiver becomes saturated. Through the use of these two modes, a receiver can continue to operate and detect a received signal whether or not interference is present. In some implementations, an interference awareness module determines whether interference is present and causes the low-noise amplifier to dynamically switch between the current and voltage modes of operation based on this determination.

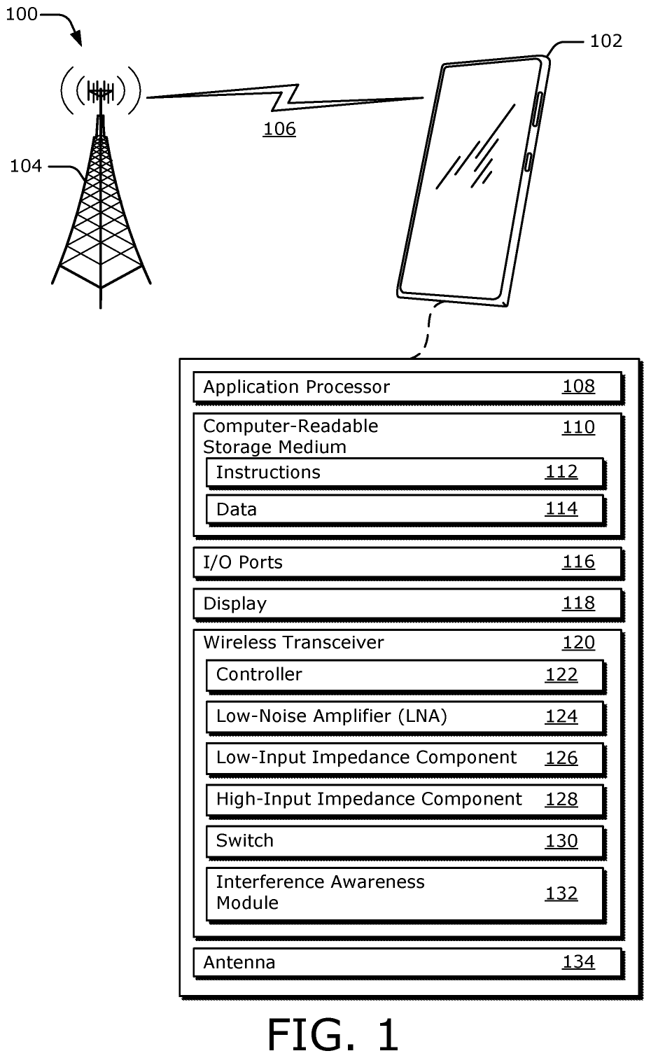

FIG. 1 illustrates an example operating environment 100 for dual-mode amplification by varying a load impedance. In the environment 100, a computing device 102 communicates with a base station 104 through a wireless communication link 106 (wireless link 106). In this example, the computing device 102 is depicted as a smart phone. However, the computing device 102 may be implemented as any suitable computing or electronic device, such as a modem, cellular base station, broadband router, access point, cellular phone, gaming device, navigation device, media device, laptop computer, desktop computer, tablet computer, wearable computer, server, network-attached storage (NAS) device, smart appliance or other internet of things (IoT) device, medical device, vehicle-based communication system, radar, radio apparatus, and so forth.

The base station 104 communicates with the computing device 102 via the wireless link 106, which may be implemented as any suitable type of wireless link. Although depicted as a tower of a cellular network, the base station 104 may represent or be implemented as another device, such as a satellite, internet server or video source, terrestrial television broadcast tower, access point, peer-to-peer device, mesh network node, fiber optic line, and so forth. Therefore, the computing device 102 may communicate with the base station 104 or another device via a wired connection, a wireless connection, or a combination thereof.

The wireless link 106 can include a downlink of data or control information communicated from the base station 104 to the computing device 102, or an uplink of other data or control information communicated from the computing device 102 to the base station 104. The wireless link 106 may be implemented using any suitable communication protocol or standard, such as 2′ Generation (2G), 3rd Generation (3G), 4^{th} Generation (4G), 5^{th} Generation (5G), IEEE 802.11 (e.g., Wi-Fi™), IEEE 802.15 (e.g., Bluetooth™), IEEE 802.16 (e.g., WiMAX′), and so forth. In some implementations, the wireless link 106 may wirelessly provide power and the base station 104 may comprise a power source.

The computing device 102 includes an application processor 108 and a computer-readable storage medium 110 (CRM 110). The application processor 108 may include any type of processor, such as a multi-core processor, that executes processor-executable code stored by the CRM 110. The CRM 110 may include any suitable type of data storage media, such as volatile memory (e.g., random access memory (RAM)), non-volatile memory (e.g., Flash memory), optical media, magnetic media (e.g., disk), and so forth. In the context of this disclosure, the CRM 110 is implemented to store instructions 112, data 114, and other information of the computing device 102, and thus does not include transitory propagating signals or carrier waves.

The computing device 102 may also include input/output ports 116 (I/O ports 116) and a display 118. The I/O ports 116 enable data exchanges or interaction with other devices, networks, or users. The I/O ports 116 may include serial ports (e.g., universal serial bus (USB) ports), parallel ports, audio ports, infrared (IR) ports, and so forth. The display 118 presents graphics of the computing device 102, such as a user interface associated with an operating system, program, or application. Alternately or additionally, the display 118 may be implemented as a display port or virtual interface, through which graphical content of the computing device 102 is presented.

A wireless transceiver 120 of the computing device 102 provides connectivity to respective networks and other electronic devices connected therewith. Alternately or additionally, the computing device 102 may include a wired transceiver, such as an Ethernet or fiber optic interface for communicating over a local network, intranet, or the Internet. The wireless transceiver 120 may facilitate communication over any suitable type of wireless network, such as a wireless local area network (LAN) (WLAN), peer-to-peer (P2P) network, mesh network, cellular network, wireless wide-area-network (WWAN), and/or wireless personal-area-network (WPAN). In the context of the example environment 100, the wireless transceiver 120 enables the computing device 102 to communicate with the base station 104 and networks connected therewith. However, the wireless transceiver 120 can also enable the computing device 102 to communicate “directly” with other devices.

The wireless transceiver 120 includes circuitry and logic for transmitting and receiving communication signals via an antenna 134. Components of the wireless transceiver 120 can include amplifiers, switches, mixers, analog-to-digital converters, filters, and so forth for conditioning the communication signals. The wireless transceiver 120 may also include logic to perform in-phase/quadrature (I/Q) operations, such as synthesis, encoding, modulation, decoding, demodulation, and so forth. In some cases, components of the wireless transceiver 120 are implemented as separate receiver and transmitter entities. Additionally or alternatively, the wireless transceiver 120 can be realized using multiple or different sections to implement respective receiving and transmitting operations (e.g., separate transmit and receiver chains). In general, the wireless transceiver 120 processes data and/or signals associated with communicating data of the computing device 102 over the antenna 134.

The wireless transceiver 120 also includes a controller 122. The controller 122 can include at least one processor and CRM, which stores computer-executable instructions (such as the application processor 108, the CRM 110, and the instructions 112). The processor and the CRM can be localized at one module or one integrated circuit chip or can be distributed across multiple modules or chips. Together, a processor and associated instructions can be realized in separate circuitry, fixed logic circuitry, hard-coded logic, and so forth. The controller 122 can be implemented as part of the wireless transceiver 120, the application processor 108, a general-purpose processor, some combination thereof, and so forth. In general, the controller 122 controls the wireless transceiver 120 or at least has knowledge of operations performed by the wireless transceiver 120.

In addition to the controller 122, the wireless transceiver 120 includes at least one low-noise amplifier 124, at least a first component (e.g., a low-input impedance component 126), at least a second component (e.g., a high-input impedance component 128), at least one switch 130, and at least one interference awareness module 132. The low-noise amplifier 124 can operates in a current mode or a voltage mode as described herein, depending on whether a load impedance of the low-noise amplifier 124 is relatively small or large, respectively. In some implementations, operating conditions or a configuration of the low-noise amplifier 124 remain relatively unchanged for different operational modes.

In example implementations of a receiver chain of the wireless transceiver 120, the low-noise amplifier 124, the high-input impedance component 128, and the low-input impedance component 126 are coupled together in series. The high-input impedance component 128 may comprise another amplifier, such as a transconductance amplifier, which produces an output current based on an input voltage. In other implementations, the high-input impedance component 128 may comprise alternative circuitry that includes a phase shifter, an active filter, or a voltage buffer. An example of a low-input impedance component 126 includes a mixer for down-converting signal frequencies. Other implementations of the low-input impedance component 126 may comprise a current buffer. In general, the high-input impedance component 128 has an input impedance that is relatively larger or greater than an input impedance of the low-input impedance component 126.

In some implementations, the switch 130 is coupled in parallel with the high-input impedance component 128 between the low-noise amplifier 124 and the low-input impedance component 126. The switch 130 can be implemented using one or more transistors, such as metal-oxide-semiconductor field-effect transistors (MOSFETs), junction field-effect transistors (JFETs), bipolar junction transistors (BJTs), and so forth. For example, the switch 130 can comprise an n-channel metal-oxide-semiconductor field-effect transistor (NMOSFET) or a p-channel metal-oxide-semiconductor field-effect transistor (PMOSFET) and can have a thin or thick gate oxide layer.

The switch 130 enables the high-input impedance component 128 to be bypassed or not bypassed (e.g., bypassed or engaged), which varies a load impedance that is “seen by” the low-noise amplifier. In a closed state, for example, the switch 130 enables the high-input impedance component 128 to be bypassed (e.g., by a receive signal propagating along the receiver chain), thereby causing a load impedance of the low-noise amplifier 124 to be based on the input impedance of the low-input impedance component 126. In an open state, however, the switch 130 engages the high-input impedance component 128, which causes the load impedance of the low-noise amplifier 124 to be based on the input impedance of the high-input impedance component 128. Thus, the low-input impedance component 126, the high-input impedance component 128, and the switch 130 can at least partially implement dual-mode amplification by varying a load impedance as described herein.

In example operations, the interference awareness module 132 determines whether or not interference is present and controls a state of the switch 130 to realize a target sensitivity. Different implementations of the interference awareness module 132 may employ detection (e.g., reactive) techniques or knowledge-based (e.g., predictive) techniques to ensure the switch 130 is in the appropriate configuration.

The interference awareness module 132 may include, for example, detection circuitry, such as an automatic gain control (AGC) circuit, which monitors a peak amplitude or power level of a receive signal at an input of the low-noise amplifier 124. If the peak amplitude or power level exceeds a threshold, the interference awareness module 132 can cause the switch 130 to be in the closed state. If the peak amplitude or power level is below the threshold, however, the interference awareness module 132 can cause the switch 130 to be in the open state.

In some implementations, a portion of the interference awareness module 132 may be implemented within the controller 122 or may be in communication with the controller 122. In this case, the interference awareness module 132 has access to information regarding times during which a transmitter within the wireless transceiver 120 is in an active mode (e.g., is actively transmitting) or an inactive mode (e.g., not actively transmitting). Using this information, the interference awareness module 132 may proactively cause the switch 130 to be in the closed state if the transmitter is about to transition to the active mode or cause the switch 130 to be in the open state responsive to the transmitter transitioning from the active mode to the inactive mode. The determination of the state of the switch 130 may also be based on a transmission frequency generated by the transmitter and whether the transmission frequency interferes with or is close to a reception frequency. By employing reactive or proactive techniques (or a combination thereof), the interference awareness module 132 can dynamically cause the low-noise amplifier 124 to be in the appropriate mode, as described herein below.

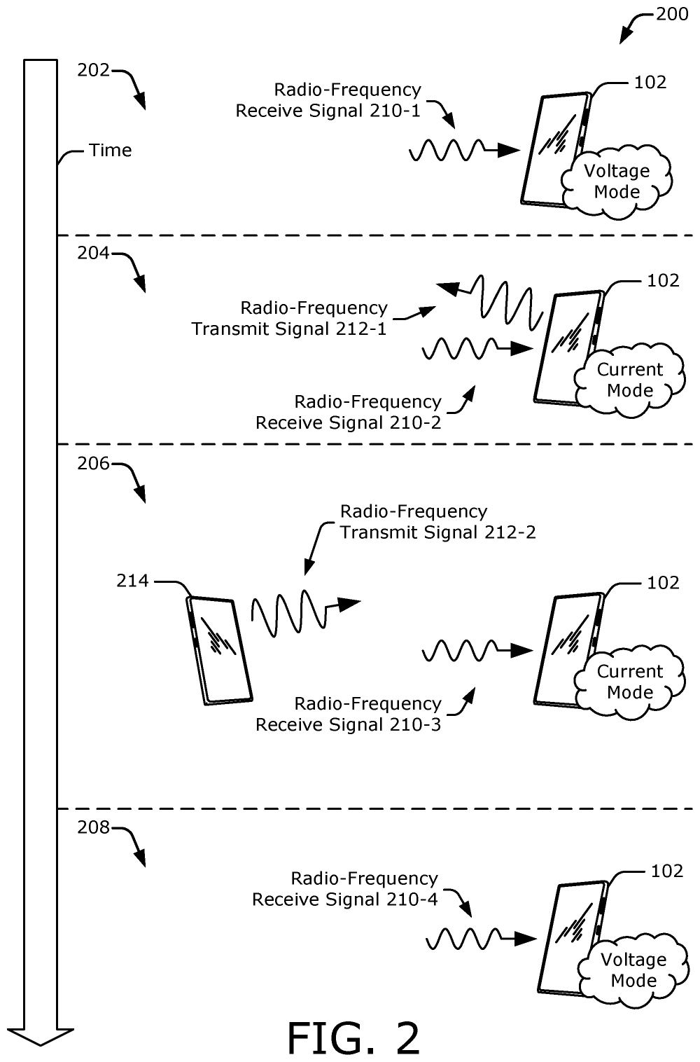

FIG. 2 illustrates an example sequence flow diagram 200 for dual-mode amplification by varying a load impedance, with time elapsing in a downward direction. Examples of a voltage mode are shown at 202 and 208, and examples of a current mode are shown at 204 and 206. The voltage mode can occur based on a determination that interference is not present (e.g., based on the wireless transceiver 120 receiving a low-power signal from the antenna 134) while the current mode can occur based on a determination that interference is present (e.g., based on the wireless transceiver 120 receiving a high-power signal from the antenna 134).

At 202, the switch 130 is in the open state and the low-noise amplifier 124 operates in the voltage mode during at least a portion of time that the computing device 102 receives a radio-frequency receive signal 210-1. Because the low-noise amplifier 124 is in the voltage mode, the wireless transceiver 120 has sufficient sensitivity to detect and process the radio-frequency receive signal 210-1.

At 204, the wireless transceiver 120 transmits a radio-frequency transmit signal 212-1 during at least a portion of time that the computing device 102 receives another radio-frequency receive signal 210-2. As a result, the radio-frequency transmit signal 212-1 may interfere with reception of the radio-frequency receive signal 210-2. At this time, the switch 130 is placed in the closed state, and the low-noise amplifier 124 operates in the current mode. Because the low-noise amplifier 124 is in the current mode, the wireless transceiver 120 has sufficient dynamic range to receive the radio-frequency transmit signal 212-1 and the radio-frequency receive signal 210-2 without becoming saturated.

At 206, another computing device 214 that is proximate to the computing device 102 transmits another radio-frequency signal 212-2 during at least a portion of time that the computing device 102 receives another radio-frequency receive signal 210-3. Similar to 204, the radio-frequency transmit signal 212-2 is also received by the wireless transceiver 120 along with the radio-frequency receive signal 210-3. At this time, the switch 130 is in the closed state, and the low-noise amplifier 124 operates in the current mode. As such, the wireless transceiver 120 has sufficient dynamic range to receive the radio-frequency transmit signal 212-2 and the radio-frequency receive signal 210-3 without becoming saturated.

At 208, the switch 130 is in the open state, and the low-noise amplifier 124 operates in the voltage mode during at least a portion of time that the computing device 102 receives another radio-frequency receive signal 210-4. This can occur responsive to the computing device 102 stopping the transmission of the radio-frequency transmit signal 212-1 or responsive to the other computing device 214 stopping the transmission of the radio-frequency transmit signal 212-2.

As described above, the current mode may be activated whether interference is self-generated (e.g., by the wireless transceiver 120) or exists within an external environment (e.g., is generated by the computing device 214). By dynamically switching between the voltage mode and the current mode, a radio-frequency receive signal 210 may be received whether interference is present or not and the performance of the wireless transceiver 120 may be appropriately adjusted according to a given situation.

In the above examples, the radio-frequency transmit signals 212-1 and 212-2 may each comprise at least one of the following signal types: a 2G cellular signal, a 3G cellular signal, a 4G cellular signal, a 5G cellular signal, a signal, a Bluetooth™ signal, and so forth. The radio-frequency receive signal 210 may be associated with a similar or a different signal type (e.g., be associated with a similar or different wireless communication standard) as the radio-frequency transmit signal 212-1 or 212-2. In some cases, a frequency of the radio-frequency transmit signal 212-1 or 212-2 is similar to the radio-frequency receive signal 210. For example, the radio-frequency transmit signal 212-1 or 212-2 and the radio-frequency receive signal 210 can have frequencies within a frequency band or contiguous spectrum. The frequency band may have a dedicated purpose defined by a government and may be publicly or privately owned. Example frequency bands include an long-term evolution (LTE) band, a band, and so forth. Additionally or alternatively, the radio-frequency transmit signal 212-1 or 212-2 and the radio-frequency receive signal 210 can have respective center frequencies that are relatively close to one another, can have respective bandwidths that overlap each other by a given amount, or can include frequencies that are harmonics of one another. In some cases, the radio-frequency transmit signal 212-1 or 212-2 may have a higher power level than the radio-frequency receive signal 210 at the antenna 134.

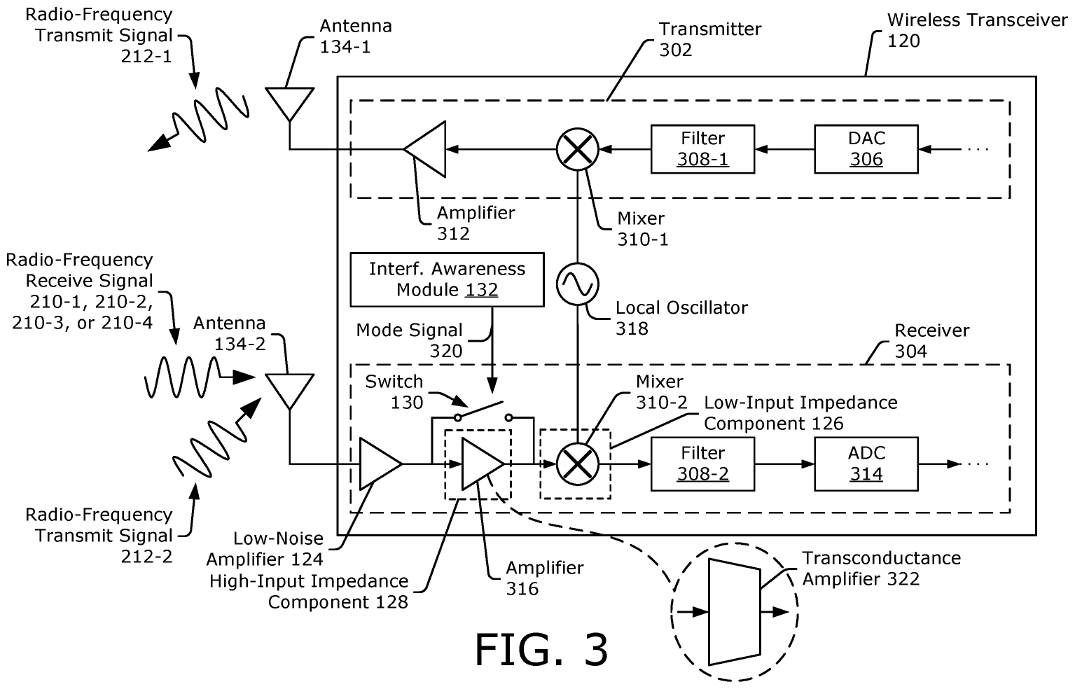

The radio-frequency transmit signals 212-1 and 212-2 respectively represent self-generated and external interference that is received at the computing device 102. While the radio-frequency transmit signals 212-1 and 212-2 are not desired signals, use of the current mode enables the wireless transceiver 120 to continue operating in the presence of this interference such that the desired radio-frequency receive signals 210-2 and 210-3 may be received and processed. The wireless transceiver 120 of the computing device 102 is further described with respect to FIG. 3.

FIG. 3 illustrates an example wireless transceiver 120 for dual-mode amplification by varying a load impedance. The wireless transceiver 120 includes a transmitter 302 and a receiver 304, which are respectively coupled to antennas 134-1 and 134-2. The transmitter 302 is shown to include a digital-to-analog converter (DAC) 306, a filter 308-1 (e.g., a low-pass filter (LPF) or a baseband filter), a mixer 310-1, and an amplifier 312. Although not explicitly shown, the transmitter 302 can also include a signal generator that is coupled to the digital-to-analog converter 306. The transmitter 302 generates the radio-frequency transmit signal 212-1, which is transmitted by the antenna 134-1.

The receiver 304 includes the low-noise amplifier (LNA) 124, the high-input impedance component 128, the low-input impedance component 126, the switch 130, a filter 308-2 (e.g., a low-pass filter or a baseband filter), and an analog-to-digital converter (ADC) 314. In the depicted configuration, the high-input impedance component 128 comprises an amplifier 316 and the low-input impedance component 126 comprises a mixer 310-2. In an example implementation, the amplifier 316 may be implemented as a transconductance amplifier 322.

The wireless transceiver 120 also includes a local oscillator 318, which generates a reference signal enabling the mixers 310-1 and 310-2 to upconvert or downconvert analog signals within the transmitter 302 or the receiver 304, respectively. The transmitter 302 and the receiver 304 can also include other additional components that are not depicted in FIG. 3, such as band-pass filters, additional mixers, switches, and so forth. Some implementations of the receiver 304 may include a variable (e.g., programmable or tunable) capacitor coupled to an output of the low-noise amplifier 124. The variable capacitor can be used to adjust an output impedance of the low-noise amplifier 124 based on a state of the switch 130 for impedance matching to a selected load impedance.

Within the wireless transceiver 120, the interference awareness module 132 may be implemented within the controller 122, within detection circuitry that is coupled to an input of the low-noise amplifier 124, or a combination thereof. The interference awareness module 132 is coupled to the switch 130 and generates a mode signal 320, which causes the switch 130 to be in the open state or the closed state. Although not explicitly shown, the interference awareness module 132 may also be coupled to the antenna 134-2 or an input of the low-noise amplifier 124 to detect the peak amplitude or power level of signals received by the antenna 134-2. Alternatively or additionally, the interference awareness module 132 may also be coupled to the transmitter 302 to determine if the transmitter 302 is in the active mode.

Due to a proximity of the transmitter 302 to the receiver 304, the transmitter 302 and the receiver 304 may be coupled together through the antennas 134-1 and 134-2, one or more pins, or at least one bondwire. As such, there may be limited isolation between the transmitter 302 and the receiver 304, which results in the radio-frequency transmit signal 212-1 interfering with reception of the radio-frequency receive signal 210-2 at 204 in FIG. 2. At other times, the receiver 304 may receive the radio-frequency transmit signal 212-2 from another computing device 214, as shown at 206 in FIG. 2. To enable the radio-frequency receive signal 210 to be received whether or not interference is present, the low-noise amplifier 124 is selectively operated in the current mode or the voltage mode, as further described with respect to FIGS. 4-1 and 4-2.

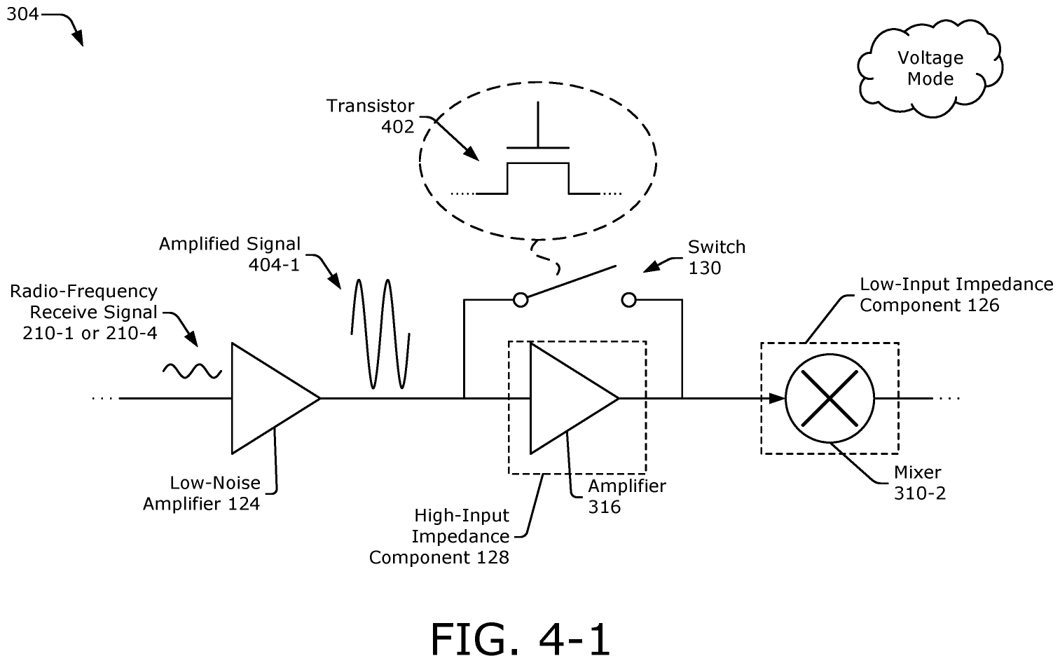

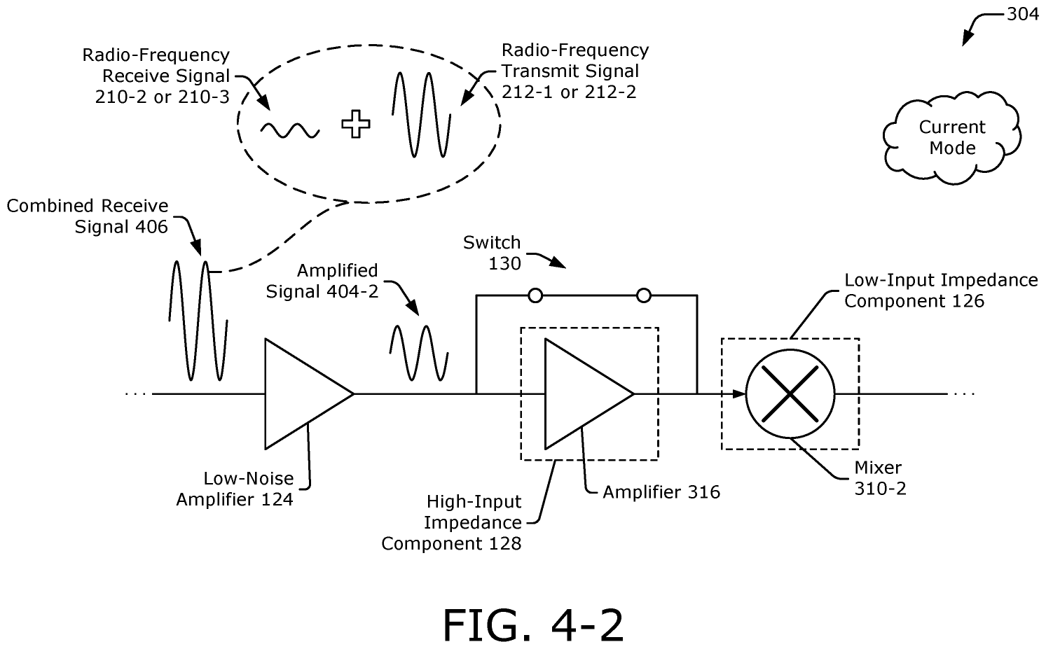

FIG. 4-1 illustrates an example voltage-mode operation of the low-noise amplifier 124 within the receiver 304 for dual-mode amplification by varying a load impedance. In the depicted configuration, interference is not present (e.g., the transmitter 302 is in an inactive mode and the computing device 214 is not transmitting the radio-frequency transmit signal 212-2). As such, the interference awareness module 132 causes the switch 130 to be in the open state, which engages the high-input impedance component 128, which is implemented as the amplifier 316 here. With the switch 130 in the open state, the low-noise amplifier 124 operates in the voltage mode because it experiences a relatively large load impedance based on the input impedance of the amplifier 316. In the voltage mode, the receiver 304 can realize improved reverse isolation and high sensitivity. Engaging the amplifier 316 can, for example, prevent a local oscillator signal generated by the local oscillator 318 of FIG. 3 from leaking from the mixer 310-2 to the antenna 134-2.

In some implementations, the switch 130 may be implemented as a transistor 402, as shown in FIG. 4-1. To cause the switch 130 to be in the open state, the interference awareness module 132 can cause a power supply or a ground potential to provide a bias voltage to operate the transistor 402 in a cut-off mode for a p-type or an n-type transistor, respectively. This bias voltage may be applied to a gate terminal of the transistor 402 (e.g., of a MOSFET).

The low-noise amplifier 124 of the receiver 304 accepts the radio-frequency receive signal 210-1 or 210-4 from the antenna 134-2 and amplifies the radio-frequency receive signal 210-1 or 210-4 to produce an amplified signal 404-1. The amplifier 316, which may be implemented as the transconductance amplifier 322 in FIG. 3, further amplifies the amplified signal 404-1 to produce a further amplified signal (not shown) for input to the mixer 310-2. Because the low-noise amplifier 124 experiences a large load impedance, the amplified signal 404-1 experiences a large voltage swing. However, if interference is present and the signal provided to an input of the low-noise amplifier 124 is therefore already relatively large, the large voltage swing may cause the receiver 304 to become saturated. As such, the low-noise amplifier 124 may alternatively operate in the current mode, as described with respect to FIG. 4-2.

FIG. 4-2 illustrates an example current-mode operation of the low-noise amplifier 124 within the receiver 304 for dual-mode amplification by varying a load impedance. In the depicted configuration, interference is present (e.g., the transmitter 302 is in an active mode and transmitting the radio-frequency transmit signal 212-1 or the computing device 214 is actively transmitting the radio-frequency transmit signal 212-2). As such, the interference awareness module 132 causes the switch 130 to be in the closed state, which bypasses the high-input impedance component 128. The high-input impedance component 128 is shown to be implemented as the amplifier 316 here. The input impedance of the low-input impedance component 126, which is implemented as the mixer 310-2 here, is small relative to the input impedance of the amplifier 316. This lower input impedance at least partially provides a relatively lower load impedance for the low-noise amplifier 124, which causes the low-noise amplifier 124 to operate in the current mode.

In operation, the low-noise amplifier 124 of the receiver 304 accepts a combined receive signal 406 from the antenna 134-2. The combined receive signal 406 represents a superposition of a desired radio-frequency receive signal 210-2 or 210-3 with an interfering radio-frequency transmit signal 212-1 or 212-2 (e.g., a jammer signal or an undesired signal). The low-noise amplifier 124 amplifies the combined receive signal 406 to produce the amplified signal 404-2. Because the low-noise amplifier 124 experiences a small load impedance, the amplified signal 404-2 has a relatively small voltage swing, which reduces a likelihood of the receiver 304 becoming saturated. Using this technique, the receiver 304 may realize improved linearity and noise figure performance relative to other techniques.

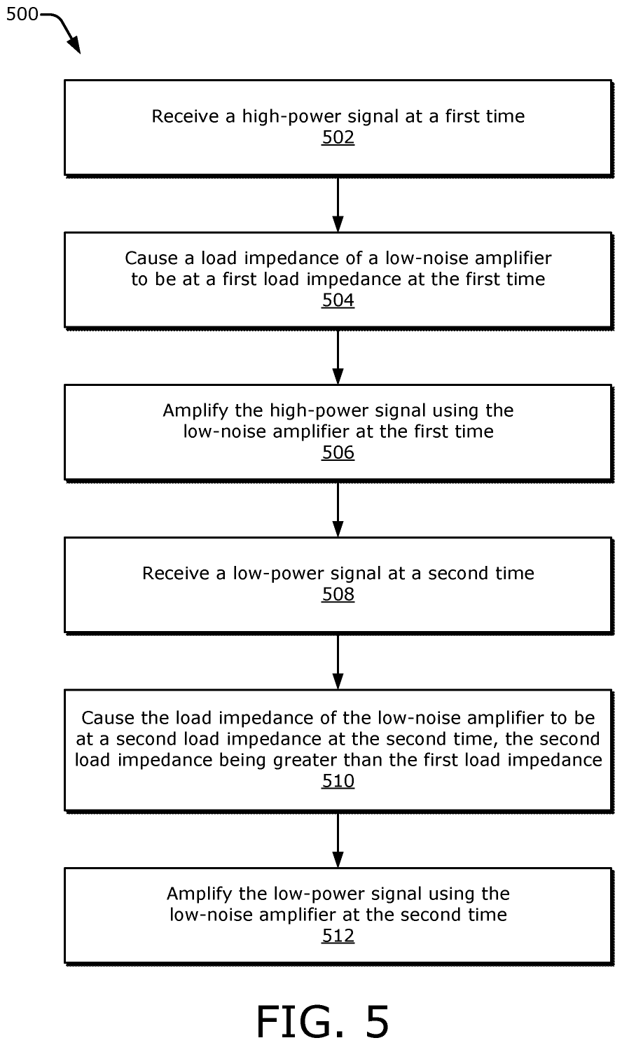

FIG. 5 is a flow diagram illustrating an example process 500 for dual-mode amplification by varying a load impedance. The process 500 is described in the form of a set of blocks 502-512 that specify operations that can be performed. However, operations are not necessarily limited to the order shown in FIG. 5 or described herein, for the operations may be implemented in alternative orders or in fully or partially overlapping manners. Operations represented by the illustrated blocks of the process 500 may be performed by a wireless transceiver 120 (e.g., of FIG. 1 or 3) or a receiver 304 (e.g., of FIG. 3). More specifically, the operations of the process 500 may be performed by a low-noise amplifier 124, a low-input impedance component 126, a high-input impedance component 128, or a switch 130, as shown in FIG. 1, 3, 4-1, or 4-2.

At 502, a high-power signal is received at a first time. For example, the receiver 304 may receive a combined receive signal 406 via the antenna 134-2 at a time associated with 204 or 206 of FIG. 2. A power level of the combined receive signal 406 may be relatively high based on a superposition of the radio-frequency receive signal 210-2 or 210-3 with the radio-frequency transmit signal 212-1 or 212-2. In other cases, the radio-frequency receive signal 210-1 or 210-4 (for a time associated with 202 or 208 of FIG. 2) may comprise a high-power signal based on the distance over which the radio-frequency receive signal 210-1 or 210-4 propagates or a transmission power level of the radio-frequency receive signal 210-1 or 210-4.

At 504, a load impedance of a low-noise amplifier is caused to be at a first load impedance at the first time. For example, the interference awareness module 132 may cause the switch 130 to be in a closed state to bypass the high-input impedance component 128, as shown in FIG. 4-2. In this case, the load impedance experienced by the low-noise amplifier 124 is based on an input impedance of the low-input impedance component 126.

At 506, the high-power signal is amplified using the low-noise amplifier at the first time. For example, the low-noise amplifier 124 can amplify the combined receive signal 406 to produce the amplified signal 404-2, as shown in FIG. 4-2, at least partly while the low-noise amplifier 124 is experiencing the load impedance that is based on the input impedance of the low-input impedance component 126.

At 508, a low-power signal is received at a second time. For example, the receiver 304 may receive a radio-frequency receive signal 210-1 or 210-4 via the antenna 134-2 at a time associated with 202 or 208 of FIG. 2. A power level of the radio-frequency receive signal 210-1 or 210-4 may be relatively low due to a distance over which the radio-frequency receive signal 210-1 or 210-4 propagates, atmospheric conditions such as rain, a transmission power level of the radio-frequency receive signal 210-1 or 210-4, or an absence of an interfering signal.

At 510, the load impedance of the low-noise amplifier is caused to be at a second load impedance at the second time. The second load impedance is greater than the first load impedance. For example, the interference awareness module 132 may cause the switch 130 to be in an open state to engage the high-input impedance component 128, as shown in FIG. 4-1. In this case, the load impedance experienced by the low-noise amplifier 124 is based on an input impedance of the high-input impedance component 128. The input impedance of the high-input impedance component 128 is greater than the input impedance of the low-input impedance component 126.

At 512, the low-power signal is amplified using the low-noise amplifier at the second time. For example, the low-noise amplifier 124 can amplify the radio-frequency receive signal 210-1 or 210-4 to produce the amplified signal 404-1, as shown in FIG. 4-1, at least partly while the low-noise amplifier 124 is experiencing the load impedance that is based on the input impedance of the high-input impedance component 128.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Further, items represented in the accompanying figures and terms discussed herein may be indicative of one or more items or terms, and thus reference may be made interchangeably to single or plural forms of the items and terms in this written description. Finally, although subject matter has been described in language specific to structural features or methodological operations, it is to be understood that the subject matter defined in the appended claims is not necessarily limited to the specific features or operations described above, including not necessarily being limited to the organizations in which features are arranged or the orders in which operations are performed.

What is claimed is:

1. An apparatus comprising:
a low-noise amplifier;
a first component having a first input impedance;
a second component coupled between the low-noise amplifier and the first component, the second component having a second input impedance that is greater than the first input impedance; and
a switch coupled in parallel with the second component between the low-noise amplifier and the first component, the switch configured to selectively be in:
an open state to engage the second component; or
a closed state to bypass the second component.

2. The apparatus of claim 1, wherein:
the first component comprises a mixer; and
the second component comprises a transconductance amplifier.

3. The apparatus of claim 1, wherein the switch comprises an n-channel metal-oxide-semiconductor field-effect transistor or a p-channel metal-oxide-semiconductor field-effect transistor.

4. The apparatus of claim 1, wherein the low-noise amplifier is configured to:
have a first load impedance be based on the first input impedance responsive to the switch being in the closed state; and
have a second load impedance be based on the second input impedance responsive to the switch being in the open state.

5. The apparatus of claim 4, wherein the low-noise amplifier is configured to:
operate in a current mode with the first load impedance responsive to the switch being in the closed state; and
operate in a voltage mode with the second load impedance responsive to the switch being in the open state.

6. The apparatus of claim 5, wherein the low-noise amplifier is configured to:
operate in the current mode to produce a first voltage swing at an output of the low-noise amplifier; and
operate in the voltage mode to produce a second voltage swing at the output of the low-noise amplifier, the second voltage swing relatively larger than the first voltage swing.

7. The apparatus of claim 1, further comprising:
a first antenna configured to receive a radio-frequency receive signal; and
a receiver coupled to the first antenna and configured to process the radio-frequency receive signal, the receiver including the low-noise amplifier, the first component, the second component, and the switch.

8. The apparatus of claim 7, further comprising:
a second antenna;
a transmitter coupled to the second antenna, the transmitter configured to selectively be in:
an active mode to transmit a radio-frequency transmit signal via the second antenna; or
an inactive mode; and
an interference awareness module coupled to the switch and configured to:
cause the switch to be in the closed state responsive to the transmitter being in the active mode; and
cause the switch to be in the open state responsive to the transmitter being in the inactive mode.

9. The apparatus of claim 8, wherein the transmitter is configured to be in the active mode during at least a portion of a time that the first antenna receives the radio-frequency receive signal.

10. The apparatus of claim 8, wherein respective frequencies of the radio-frequency transmit signal and the radio-frequency receive signal are within a frequency band.

11. The apparatus of claim 8, wherein the radio-frequency transmit signal and the radio-frequency receive signal each comprise a signal type selected from a group of signal types comprising:
a fourth-generation (4G) cellular signal;
a fifth-generation (5G) cellular signal;
a Wi-Fi™ signal; or
a Bluetooth™ signal.

12. The apparatus of claim 7, further comprising an interference awareness module coupled to the switch, wherein:
the first antenna is configured to receive a radio-frequency transmit signal during at least a portion of a time the radio-frequency receive signal is received, the radio-frequency transmit signal received from another apparatus; and
the interference awareness module is configured to:
detect the radio-frequency transmit signal; and
cause the switch to be in the closed state responsive to detection of the radio-frequency transmit signal.

13. An apparatus comprising:
a low-noise amplifier;
a first component having a first input impedance;
a second component coupled between the low-noise amplifier and the first component, the second component configured to have a second input impedance that is greater than the first input impedance; and
switch means for selectively causing a load impedance of the low-noise amplifier to be based on the first input impedance or the second input impedance.

14. The apparatus of claim 13, wherein:
the first component comprises a mixer; and
the second component comprises a transconductance amplifier.

15. The apparatus of claim 13, wherein the switch means comprises:
bypass means for causing the low-noise amplifier to operate in a current mode responsive to the load impedance being based on the first input impedance; and
engagement means for causing the low-noise amplifier to operate in a voltage mode responsive to the load impedance being based on the second input impedance.

16. The apparatus of claim 13, further comprising:
a first antenna configured to receive a radio-frequency receive signal; and
a receiver coupled to the first antenna and configured to process the radio-frequency receive signal, the receiver including the low-noise amplifier, the first component, the second component, and the switch means.

17. The apparatus of claim 16, further comprising:
a second antenna;
a transmitter coupled to the second antenna, the transmitter configured to selectively be in:
an active mode to transmit a radio-frequency transmit signal via the second antenna; or
an inactive mode; and
interference awareness means for controlling the load impedance of the low-noise amplifier via the switch means based on whether the transmitter is in the active mode or the inactive mode.

18. The apparatus of claim 17, wherein the interference awareness means is configured to:
cause the load impedance of the low-noise amplifier to be based on the first input impedance responsive to the transmitter being in the active mode; and
cause the load impedance to be based on the second input impedance responsive to the transmitter being in the inactive mode.

19. The apparatus of claim 16, further comprising:
interference awareness means for detecting a radio-frequency transmit signal and controlling the load impedance of the low-noise amplifier via the switch means based on the detection of the radio-frequency transmit signal,
wherein the first antenna is configured to receive the radio-frequency transmit signal during at least a portion of a time the radio-frequency receive signal is received, the radio-frequency transmit signal received from another apparatus.

20. A method for dual-mode amplification by varying a load impedance, the method comprising:
receiving a high-power signal at a first time;
causing a load impedance of a low-noise amplifier to be at a first load impedance at the first time;
amplifying the high-power signal using the low-noise amplifier at the first time;
receiving a low-power signal at a second time;
causing the load impedance of the low-noise amplifier to be at a second load impedance at the second time, the second load impedance being greater than the first load impedance; and
amplifying the low-power signal using the low-noise amplifier at the second time.

21. The method of claim 20, wherein the receiving of the high-power signal at the first time comprises receiving a larger amount of interference at the first time relative to an amount of interference present within the low-power signal at the second time.

22. The method of claim 21, further comprising:
detecting the larger amount of interference that is present within the high-power signal at the first time; and
causing the load impedance of the low-noise amplifier to be at the first load impedance based on the detecting.

23. The method of claim 22, wherein the detecting of the larger amount of interference comprises determining a peak amplitude of the high-power signal at an input of the low-noise amplifier is greater than a threshold at the first time.

24. The method of claim 20, wherein the causing of the load impedance of the low-noise amplifier to be at the first load impedance comprises closing a switch to bypass a high-input impedance component that is coupled to an output of the low-noise amplifier.

25. The method of claim 24, wherein the causing of the load impedance of the low-noise amplifier to be at the second load impedance comprises opening the switch to engage the high-input impedance component.

26. An apparatus comprising:
a receiver including:
a low-noise amplifier;
a mixer;
a transconductance amplifier coupled between the low-noise amplifier and the mixer; and
a switch coupled in parallel with the transconductance amplifier between the low-noise amplifier and the mixer.

27. The apparatus of claim 26, wherein:
the mixer has a first input impedance;
the transconductance amplifier has a second input impedance; and
the switch is configured to selectively:
be in a closed state to cause a load impedance of the low-noise amplifier to be based on the first input impedance; or
be in an open state to cause the load impedance to be based on the second input impedance.

28. The apparatus of claim 27, wherein the second input impedance is greater than the first input impedance.

29. The apparatus of claim 27, further comprising an antenna, the antenna configured to:
receive a high-power signal at a first time; and
receive a low-power signal at a second time, wherein:
the low-noise amplifier is configured to:
amplify the high-power signal at the first time to produce a first amplified signal; and
amplify the low-power signal at the second time to produce a second amplified signal;
the transconductance amplifier is configured to further amplify the second amplified signal at the second time;
the mixer is configured to:
downconvert the first amplified signal at the first time; and
downconvert the second amplified signal at the second time; and
the switch is configured to:
be in the closed state at the first time to bypass the transconductance amplifier and pass the first amplified signal from the low-noise amplifier to the mixer; and
be in the open state at the second time to cause the transconductance amplifier to further amplify the second amplified signal at the second time.

30. The apparatus of claim 29, wherein the high-power signal comprises a larger amount of interference relative to the low-power signal.
